(19) United States
(12) Patent Application Publication
(10) Pub. No.: US 2022/0005721 A1
(43) Pub. Date: Jan. 6, 2022

(54) METHOD OF ALIGNING WAFER

(71) Applicant: MPI Corporation, Hsinchu County (TW)

(72) Inventors: Yung-Chin LIU, Hsinchu County (TW); Chien-Hung CHEN, Hsinchu County (TW); Men-Han LEE, Hsinchu County (TW)

(21) Appl. No.: 16/920,381

(22) Filed: Jul. 2, 2020

(51) Int. Cl. H01L 21/68; G06T 7/00; G06T 7/73; H01L 21/687

(52) U.S. Cl. CPC H01L 21/681; G06T 7/0004; G06T 2207/30148; H01L 21/68714; G06T 7/73

(57) ABSTRACT

A method of aligning a wafer includes defining a reference direction for aligning the wafer; capturing an image of the wafer held on a chuck; using an identifying module to analyze a straight line on the image of the wafer; calculating an offset angle between the straight line and the reference direction; and calibrating the offset angle to align the straight line with the reference direction by way rotating the chuck.

### BACKGROUND

### Technical Field

The present disclosure relates to methods of aligning a wafer. More particularly, the present disclosure relates to wafers held by wafer probe stations.

### Description of Related Art

As the demand for electronic devices has been increasing nowadays, the quality of the components of the electronic devices correspondingly becomes an important issue of the semiconductor industry. Apart from the improving technology of manufacture for the components, the accuracy of testing for the components has also become more important.

For example, wafer probe stations are in general used to test the quality of the wafers or dies in the semiconductor industry. Hence, the operational accuracy of wafer probe stations is undoubtedly concerned.

### SUMMARY

A technical aspect of the present disclosure is to provide a method of aligning a wafer, which can allow the wafer to be aligned in an easy and efficient manner regardless of the patterns appeared on the dies disposed on the wafer.

According to an embodiment of the present disclosure, a method of aligning a wafer is provided. The method includes defining a reference direction for aligning the wafer; capturing an image of the wafer held on a chuck; using an identifying module to analyze a straight line on the image of the wafer; calculating an offset angle between the straight line and the reference direction; and calibrating the offset angle to align the straight line with the reference direction by way rotating the chuck.

In one or more embodiments of the present disclosure, the straight line is identified by a longest solid line formed by a continuous arrangement of a plurality of dots in the image.

In one or more embodiments of the present disclosure, the straight line is an edge of a die disposed on the wafer.

In one or more embodiments of the present disclosure, the straight line is identified by a longest hidden line formed by a continuous arrangement of a plurality of lines in the image.

In one or more embodiments of the present disclosure, the lines are edges of a plurality of pads disposed on the wafer.

According to another embodiment of the present disclosure, a method of aligning a wafer is provided. The method includes defining a reference direction for aligning the wafer; capturing a plurality of images of the wafer held on a chuck; integrating the images to form an integrated image; using an identifying module to analyze a straight line on the integrated image of the wafer; calculating an offset angle between the straight line and the reference direction; and calibrating the offset angle to align the straight line with the reference direction by way rotating the chuck.

In one or more embodiments of the present disclosure, each of the images at least partially overlaps with at least one of the adjacent images.

In one or more embodiments of the present disclosure, the straight line is identified by a longest solid line formed by a continuous arrangement of a plurality of dots in the integrated image.

In one or more embodiments of the present disclosure, the straight line is an edge of a die disposed on the wafer.

In one or more embodiments of the present disclosure, the straight line is identified by a longest hidden line formed by a continuous arrangement of a plurality of lines in the integrated image.

In one or more embodiments of the present disclosure, the lines are edges of a plurality of pads disposed on the wafer.

When compared with the prior art, the above-mentioned embodiments of the present disclosure have at least the following advantages:

(1) Since the alignment of the wafer based on the aligning method does not take into account the pattern appeared on the dies which are disposed on the wafer, the alignment of the wafer is easy and efficient.

(2) Since the straight line analyzed is the longest line in the image, the alignment of the wafer has a high accuracy, facilitating an accurate operation of the wafer probe station in the subsequent procedures.

(3) Since either the solid line formed by the edge of one of the dies or the hidden line formed by the edges of a number of the pads can be identified as the straight line, which is then used to calculate the offset angle with the reference direction for aligning the wafer. Thus, the aligning method can be conveniently adopted in a flexible manner.

### BRIEF DESCRIPTION OF THE DRAWINGS

The disclosure can be more fully understood by reading the following detailed description of the embodiments, with reference made to the accompanying drawings as follows:

FIG. 1 is a schematic view of a wafer probe station according to an embodiment of the present disclosure;

FIG. 2 is a flow diagram of a method of aligning a wafer according to an embodiment of the present disclosure;

FIG. 3 is a graphic view of the image of the wafer captured by the microscope of FIG. 1 and displayed on a screen, in which the wafer forms an offset angle with the reference direction of alignment of the wafer;

FIG. 4 is a graphic view of the image of the wafer captured by the microscope of FIG. 1 and displayed on a screen, in which the wafer aligns with the reference direction of alignment of the wafer;

FIG. 5 is a flow diagram of a method of aligning a wafer according to a further embodiment of the present disclosure; and

FIG. 6 is a graphic view of an integrated image formed and displayed on a screen according to another embodiment of the present disclosure.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

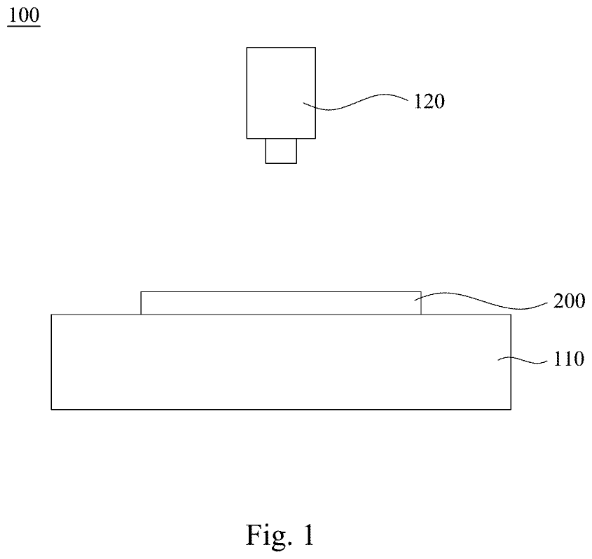

Reference is made to FIG. 1. FIG. 1 is a schematic view of a wafer probe station 100 according to an embodiment of the present disclosure. In this embodiment, as shown in FIG. 1, a wafer probe station 100 includes a chuck 110 and a microscope 120. A wafer 200 is held on the chuck 110. The chuck 110 is practically rotatable and movable three dimensionally. The microscope 120 is disposed above the chuck 110 and is movable relative to the chuck 110. The microscope 120 is configured to capture an image of the wafer 200. For the sake of simplicity of the figure, other components of the wafer probe station 100 are not shown in FIG. 1.

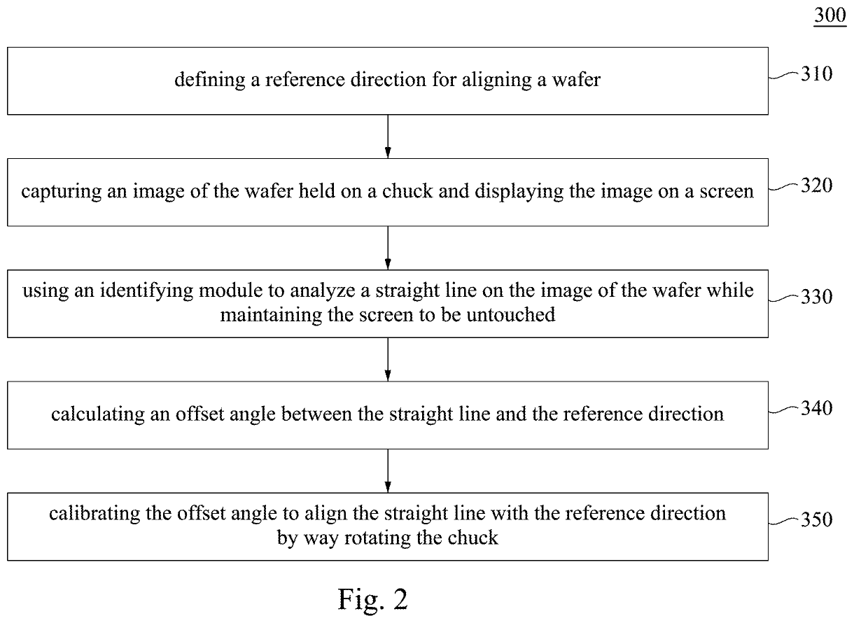

Reference is made to FIG. 2. FIG. 2 is a flow diagram of a method 300 of aligning a wafer 200 according to an embodiment of the present disclosure. As shown in FIG. 2, in this embodiment, the aligning method 300 includes the following steps (it should be noted that the sequence of the steps and the sub-steps as mentioned below, unless otherwise specified, can all be adjusted upon the actual needs, or even executed at the same time or partially at the same time):

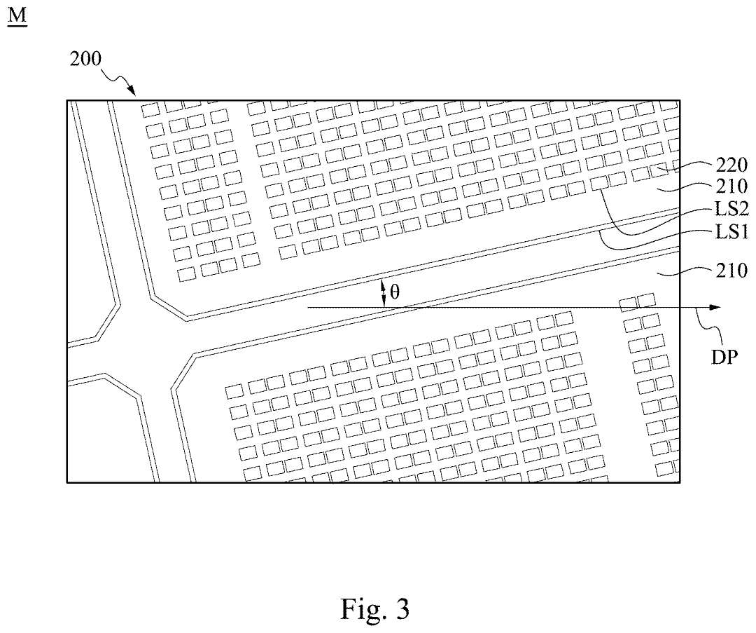

(1) Defining a reference direction DP (please refer to FIG. 3) for aligning the wafer 200 (Step 310). To be specific, the reference direction DP is the direction along which the wafer 200 should be aligned for subsequent operation of the wafer probe station 100. In practice, for instance, the reference direction DP can be along a vertical direction or a horizontal direction of the chuck 110. However, this does not intend to limit the present disclosure. In other embodiments, the reference direction DP can be any direction upon particular requirements.

(2) Capturing an image M of the wafer 200 held on the chuck 110 of the wafer probe station 100 and displaying the image M on a screen (Step 320). Reference is made to FIG. 3. FIG. 3 is a graphic view of the image M of the wafer 200 captured by the microscope 120 of FIG. 1 and displayed on a screen, in which the wafer 200 forms an offset angle θ with the reference direction DP of alignment of the wafer 200. In this embodiment, as shown in FIG. 3, there is a plurality of dies 210 disposed on the wafer 200 as displayed on a screen. Before alignment of the wafer 200 is carried out, for example, the wafer 200 forms an offset angle θ with the reference direction DP for aligning the wafer 200. To be specific, at least one of the edges of each of the dies 210 forms an offset angle θ with the reference direction DP for aligning the wafer 200. However, in practice, please be noted that displaying the image M on the screen is not mandatory since the information as captured in the image M is directly processed by an identifying module.

(3) Using an identifying module to analyze a straight line LS1 on the image M of the wafer 200 while maintaining the screen to be untouched (Step 330). In the image M of the wafer 200 captured by the microscope 120 and displayed on the screen as shown in FIG. 3, the straight line LS1 on the wafer 200, which is the longest straight line in the image M, is analyzed by an identifying module. In practical applications, for example, the identifying module can be a firmware. It is worth to note that, when analyzing the straight line LS1 in the image M on the screen, if available, the user is not required to touch the screen to input any instruction since the information as captured in the image M is directly processed by the identifying module, as mentioned above. In other words, the screen, if available, is maintained to be untouched during the process of analyzing the straight line LS1 on the image M on the screen. Graphically speaking, the straight line LS1 is the longest solid line formed by a continuous arrangement of a plurality of dots in the image M. In practical applications, the straight line LS1 is an edge of one of the dies 210 disposed on the wafer 200, and the edge is presented in the image M graphically as a series of dots connected together.

(4) Calculating an offset angle θ between the straight line LS1 and the reference direction DP for aligning the wafer 200 (Step 340). After the straight line LS1 on the wafer 200 is analyzed on the image M on the screen, the offset angle θ between the straight line LS1 and the reference direction DP is calculated.

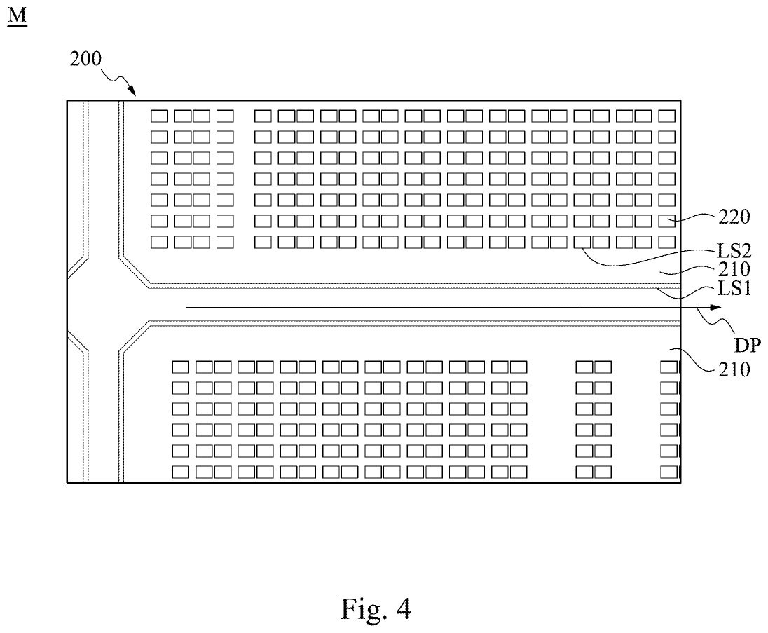

(5) Calibrating the offset angle θ to align the straight line LS1 with the reference direction DP for aligning the wafer 200 by way rotating the chuck 110 (Step 350). Reference is made to FIG. 4. FIG. 4 is a graphic view of the image M of the wafer 200 captured by the microscope 120 of FIG. 1 and displayed on a screen, in which the wafer 200 aligns with the reference direction DP for aligning the wafer 200. After the offset angle θ is calculated and known, the chuck 110 is rotated by the offset angle θ such that the offset angle θ vanishes and the straight line LS1 aligns with the reference direction DP. In other words, the straight line LS1 is parallel with the reference direction DP, which effectively facilitates the subsequent procedures of the wafer probe station 100.

It is worth to note that, since the alignment of the wafer 200 based on the aligning method 300 does not take into account the patterns appeared on the dies 210 which are disposed on the wafer 200, the alignment of the wafer 200 is easy and efficient. Moreover, since the straight line LS1 analyzed is the longest line in the image M, the alignment of the wafer 200 has a high accuracy, facilitating an accurate operation of the wafer probe station 100 in the subsequent procedures.

On the other hand, according to the actual situation, the straight line LS2 can be identified by the longest hidden line formed by a continuous arrangement of a plurality of lines LP in the images M, as shown in FIGS. 3-4. In practical applications, the lines LP are edges of a plurality of pads 220 disposed regularly on the wafer 200, or on the dies 210, in some embodiments. The edges of the pads 220 are presented in the image M graphically as a series of short lines arranged and extending along the same direction.

In other words, according to the actual situation, either the solid line formed by the edge of one of the dies 210 or the hidden line formed by the edges of a number of the pads 220 can be identified as the straight line, which is then used to calculate the offset angle θ with the reference direction DP for aligning the wafer 200. Thus, the aligning method 300 can be conveniently adopted in a flexible manner.

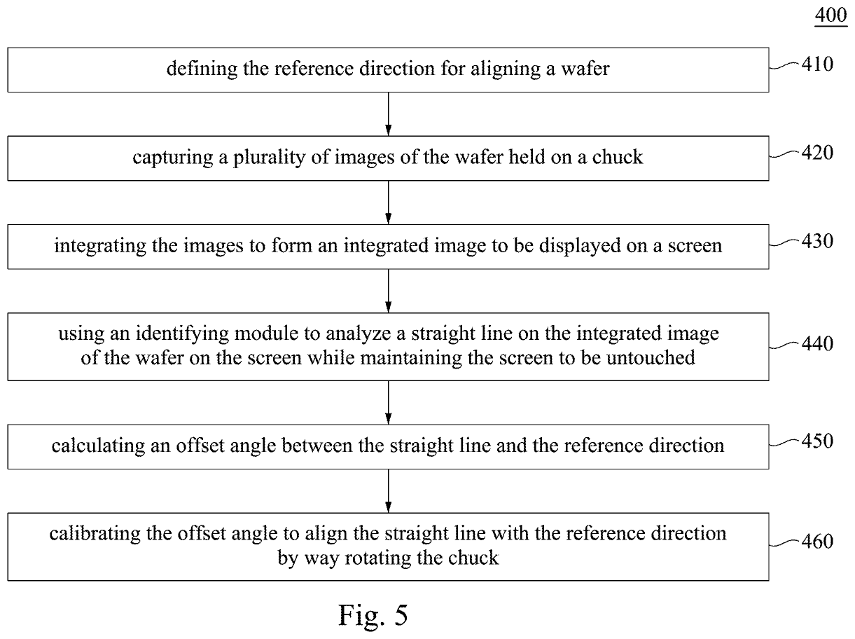

Reference is made to FIG. 5. FIG. 5 is a flow diagram of a method 400 of aligning a wafer 200 according to a further embodiment of the present disclosure. The main difference between the aligning method 400 and the aligning method 300 is that in the aligning method 400, a plurality of images M instead of a single one of the image M of the wafer 200 are captured, such that the straight line LS with an even longer length is obtained, which could increase the accuracy of alignment of the wafer 200.

In details, in this embodiment, as shown in FIG. 5, the aligning method 400 includes the following steps (it should be noted that the sequence of the steps and the sub-steps as mentioned below, unless otherwise specified, can all be adjusted upon the actual needs, or even executed at the same time or partially at the same time):

(1) Defining the reference direction DP for aligning the wafer 200 (Step 410).

(2) Capturing a plurality of images M of the wafer 200 held on the chuck 110 of the wafer probe station 100 (Step 420).

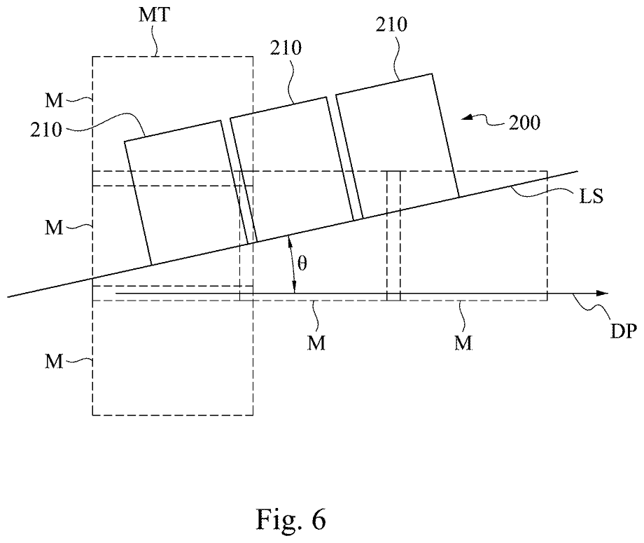

(3) Integrating the images M to form an integrated image MT to be displayed on a screen (Step 430). Reference is made to FIG. 6. FIG. 6 is a graphic view of an integrated image MT formed and displayed on a screen according to another embodiment of the present disclosure. In this embodiment, as shown in FIG. 6, a plurality of the images M are integrated together to form an integrated image MT and displayed on the screen. Moreover, in order to achieve a complete and precise integration of the integrated image MT from the images M, each of the images M at least partially overlaps with at least one of the adjacent images M. However, in practice, please be noted that displaying the integrated image MT on the screen is not mandatory since the information as captured in the images M is directly processed by an identifying module.

(4) Using an identifying module to analyze a straight line LS on the integrated image MT of the wafer 200 on the screen while maintaining the screen to be untouched (Step 440). Since the integrated image MT is formed from a plurality of the images M, the length of the straight line LS to be analyzed by an identifying module in the integrated image MT can have an even longer length. In practical applications, for example, the identifying module can be a firmware. Similarly, it is worth to note that, when analyzing the straight line LS in the integrated image MT on the screen, if available, the user is not required to touch the screen to input any instruction since the information as captured in the images M is directly processed by the identifying module, as mentioned above. In other words, the screen, if available, is maintained to be untouched during the process of analyzing the straight line LS on the integrated image MT on the screen.

(5) Calculating an offset angle θ between the straight line LS and the reference direction DP for aligning the wafer 200 (Step 450). As mentioned above, since the length of the straight line LS analyzed in the integrated image MT has a longer length than that analyzed in a single image M, the accuracy of the alignment of the wafer 200 is further improved.

(6) Calibrating the offset angle θ to align the straight line LS with the reference direction DP for aligning the wafer 200 by way rotating the chuck 110 (Step 460). In other words, the offset angle θ vanishes and the straight line LS is parallel with the reference direction DP, which effectively facilitates the subsequent procedures of the wafer probe station 100.

In conclusion, when compared with the prior art, the aforementioned embodiments of the present disclosure have at least the following advantages:

(1) Since the alignment of the wafer based on the aligning method does not take into account the pattern appeared on the dies which are disposed on the wafer, the alignment of the wafer is easy and efficient.

(2) Since the straight line analyzed is the longest line in the image, the alignment of the wafer has a high accuracy, facilitating an accurate operation of the wafer probe station in the subsequent procedures.

(3) Since either the solid line formed by the edge of one of the dies or the hidden line formed by the edges of a number of the pads can be identified as the straight line, which is then used to calculate the offset angle with the reference direction for aligning the wafer. Thus, the aligning method can be conveniently adopted in a flexible manner.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A method of aligning a wafer, the method comprising:
defining a reference direction for aligning the wafer;
capturing an image of the wafer held on a chuck;
using an identifying module to analyze a straight line on the image of the wafer;
calculating an offset angle between the straight line and the reference direction; and
calibrating the offset angle to align the straight line with the reference direction by way rotating the chuck.

2. The aligning method of claim 1, wherein the straight line is identified by a longest solid line formed by a continuous arrangement of a plurality of dots in the image.

3. The aligning method of claim 2, wherein the straight line is an edge of a die disposed on the wafer.

4. The aligning method of claim 1, wherein the straight line is identified by a longest hidden line formed by a continuous arrangement of a plurality of lines in the image.

5. The aligning method of claim 4, wherein the lines are edges of a plurality of pads disposed on the wafer.

6. A method of aligning a wafer, the method comprising:
defining a reference direction for aligning the wafer;
capturing a plurality of images of the wafer held on a chuck;
integrating the images to form an integrated image;
using an identifying module to analyze a straight line on the integrated image of the wafer;
calculating an offset angle between the straight line and the reference direction; and
calibrating the offset angle to align the straight line with the reference direction by way rotating the chuck.

7. The aligning method of claim 6, wherein each of the images at least partially overlaps with at least one of the adjacent images.

8. The aligning method of claim 6, wherein the straight line is identified by a longest solid line formed by a continuous arrangement of a plurality of dots in the integrated image.

9. The aligning method of claim 8, wherein the straight line is an edge of a die disposed on the wafer.

10. The aligning method of claim 6, wherein the straight line is identified by a longest hidden line formed by a continuous arrangement of a plurality of lines in the integrated image.

11. The aligning method of claim 10, wherein the lines are edges of a plurality of pads disposed on the wafer.
